(19) United States
(12) Patent Application Publication
(10) Pub. No.: US 2025/0364388 A1
(43) Pub. Date: Nov. 27, 2025

(54) MICROELECTRONIC ASSEMBLIES INCLUDING SUBSTRATES WITH VIA CLUSTERING FOR HIGH-SPEED SIGNALING

(71) Applicant: Intel Corporation, Santa Clara, CA (US)

(72) Inventors: Saikat Mondal, Chandler, AZ (US); Dhanya Athreya, Chandler, AZ (US); Sri Chaitra Jyotsna Chavali, Chandler, AZ (US); Oluwafemi Akinwale, Hayward, CA (US); Zhichao Zhang, Chandler, AZ (US)

(73) Assignee: Intel Corporation, Santa Clara, CA (US)

(21) Appl. No.: 18/671,230

(22) Filed: May 22, 2024

(51) Int. Cl. H01L 23/498; H01L 23/00

(52) U.S. Cl. CPC H01L 23/49838; H01L 23/49827; H01L 24/16; H01L 23/49822; H01L 24/32; H01L 24/73; H01L 2224/16227; H01L 2224/32225; H01L 2224/73204

(57) ABSTRACT

Microelectronic assemblies, related devices and methods, are disclosed herein. In some embodiments, a microelectronic assembly may include a substrate having a first layer including a first conductive pad at a first surface of the substrate; a second layer, adjacent to the first layer, including first conductive vias, wherein one or two first conductive vias are physically coupled to the first conductive pad; a third layer including second conductive vias; and a fourth layer, adjacent to the third layer, including a second conductive pad at a second surface opposite the first surface of the substrate, wherein between four and nineteen second conductive vias are physically coupled to the second conductive pad, and the first conductive pad is electrically coupled to the second conductive pad by at least the first conductive vias and the second conductive vias.

### BACKGROUND

Integrated circuit (IC) devices (e.g., dies) are typically coupled together in a multi-die IC package to integrate features or functionality and to facilitate connections to other components, such as package substrates.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1A is a side, cross-sectional view of an example microelectronic assembly, in accordance with various embodiments.

FIG. 1B is a side, cross-sectional view of another example microelectronic assembly, in accordance with various embodiments.

FIG. 2A is a simplified schematic cross-sectional view of another example microelectronic assembly, in accordance with various embodiments.

FIG. 2B is a magnified, three-dimensional, perspective view of a portion of the microelectronic assembly of FIG. 2A, in accordance with various embodiments.

FIGS. 3A-3C illustrate bottom views of pad layers and via layers including example numbers and arrangements of vias coupled to the adjacent pad layers that are stacked vertically to form pyramidal shaped via clusters, in accordance with various embodiments.

FIGS. 4A-4C illustrate bottom views of pad layers and via layers including example numbers and arrangements of vias coupled to the adjacent pad layers that are stacked vertically to form pyramidal shaped via clusters, in accordance with various embodiments.

FIGS. 5A-5C illustrate bottom views of pad layers and via layers including example numbers and arrangements of vias coupled to the adjacent pad layers that are stacked vertically to form pyramidal shaped via clusters, in accordance with various embodiments.

FIG. 6 is a cross-sectional side view of an IC device assembly that may include a microelectronic assembly, in accordance with any of the embodiments disclosed herein.

FIG. 7 is a block diagram of an example electrical device that may include a microelectronic assembly, in accordance with any of the embodiments disclosed herein.

### DETAILED DESCRIPTION

### Overview

Communicating large numbers of signals between two or more dies in a multi-die IC package is challenging due to the increasingly small size of such dies and increased use of stacking dies. Multi-die IC packaging typically requires increased die segregation, additional power delivery requirements, and stricter routing and alignment tolerances throughout the package. The greater number of dies and smaller size of dies vastly increases manufacturing complexity as well as routing complexity. Generally, in an IC package, a high-speed signal is routed from a top die through conductive pathways in a substrate to ball grid array (BGA) pads that are electrically coupled to a circuit board by solder interconnects. The conductive pathways through the substrate usually include traces, pads, and vias, where vias are vertical structures that couple traces and/or pads in adjacent layers. Single layer vias may be arranged to be stacked vertically across multiple layers to provide an inductive path between traces and/or pads at different layers. A diameter of a via is determined by the package manufacturing technology. Typically, the IC package is attached to the circuit board using surface-mount technology, which may cause warpage and change the BGA shape. A wider BGA shape is more capacitive in nature. When a high-speed signal transitions from an inductive via region to a capacitive BGA region, the signal experiences more reflections at higher frequency. Conventionally, a width of the solder joint is regulated to achieve signal integrity benefits at a higher frequency. However, for increased reliability and a low-cost solution, solder joint width reduction may not be possible beyond a certain limit. A taller solder joint shape is preferred over a wider solder joint shape to maintain less reflection while a wider solder joint is preferred over a taller solder joint for maintaining a stringent solder joint reliability. The microelectronic structures and assemblies disclosed herein may achieve high-speed signal integrity with a wider solder joint by electrically coupling a plurality of vias to a single BGA pad (e.g., clustering the vias). Vias may be clustered over multiple layers to form a pyramid-shaped transition of the vias from a top surface of the substrate towards a bottom surface (e.g., the BGA layer). Such a gradual widening of the signal path towards a BGA pad provides a high-speed signal path with less reflection at a higher frequency to a wider solder joint. Further, the microelectronic structures and assemblies disclosed herein offer flexibility to electronics designers and manufacturers, allowing them to select an architecture that achieves their device goals with standard design rules and current manufacturing processes, and without added excess cost or complexity.

Accordingly, microelectronic assemblies, related devices and methods, are disclosed herein. In some embodiments, a microelectronic assembly may include a substrate having a first layer including a first conductive pad at a first surface of the substrate; a second layer, adjacent to the first layer, including first conductive vias, wherein one (1) or two (2) first conductive vias are physically coupled to the first conductive pad; a third layer including second conductive vias; and a fourth layer, adjacent to the third layer, including a second conductive pad at a second surface opposite the first surface of the substrate, wherein between four (4) and nineteen (19) second conductive vias are physically coupled to the second conductive pad, and the first conductive pad is electrically coupled to the second conductive pad by at least the first conductive vias and the second conductive vias.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” (IC) means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or IlI-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die,” “IC,” and “IC die.” Note that the terms “microelectronic component,” “chip,” “chiplet,” “die,” “IC,” and “IC die,” and similar variations may be used interchangeably herein. The terms “interconnect component,” “bridge die,” “interconnect bridge,” and “interconnect die,” and similar variations may be used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. A dielectric material may include any suitable dielectric material commonly used in semiconductor manufacture, such as silicon and one or more of oxygen, nitrogen, hydrogen, and carbon (e.g., in the form of silicon oxide, silicon nitride, silicon oxynitride, or silicon carbon nitride); a polyimide material; or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides, including optical fiber, optical splitters, optical combiners, optical couplers, and optical vias.

As used herein, the term “optical element” includes arrangements of forms fabricated in ICs to receive, transform and/or transmit optical signals as described herein. It may include optical conductors such as waveguides, grating coupler, electromagnetic radiation sources such as lasers, and electro-optical devices such as photodetectors.

The term “waveguide” refers to any structure that acts to confine and guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing (e.g., a laser written waveguide). Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive vertical element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

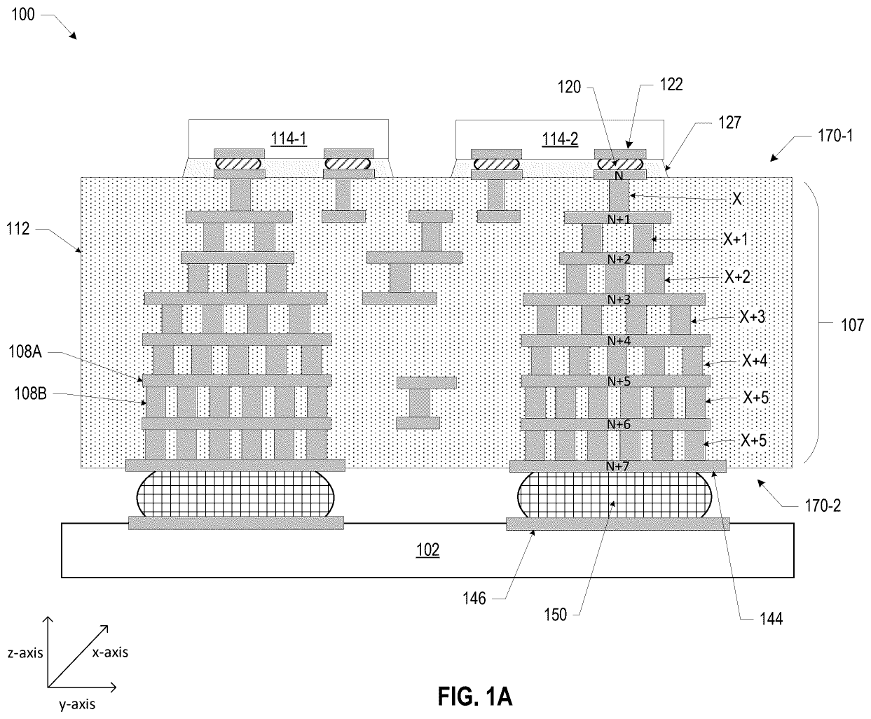

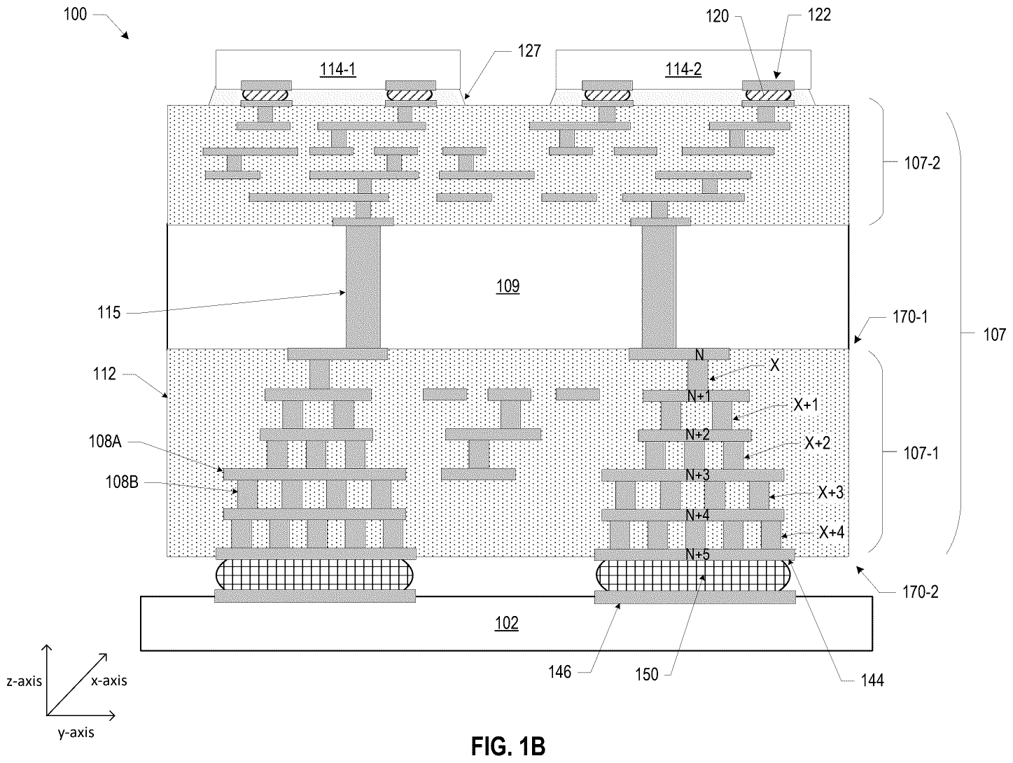

For convenience, if a collection of drawings designated with different letters are present (e.g., FIGS. 1A and 1B), such a collection may be referred to herein without the letters (e.g., as “FIG. 1”). Similarly, if a collection of reference numerals designated with different numerals and/or letters are present (e.g., 108A, 108B, 108A-1, 108B-1, etc.), such a collection may be referred to herein without the numerals and/or letters (e.g., as “108”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

FIG. 1A is a side, cross-sectional view of an example microelectronic assembly, in accordance with various embodiments. As shown in FIG. 1A, the microelectronic assembly 100 may include a substrate 107 with conductive pathways 108 through a dielectric material 112, where the conductive pathways 108 include alternating layers of pads 108A (e.g., layers N through N+7) and vias, where the number of vias (e.g., X through X+5) coupled to adjacent layers of pads 108A increases with the increasing number of layers of pads (e.g., layers N through N+7).

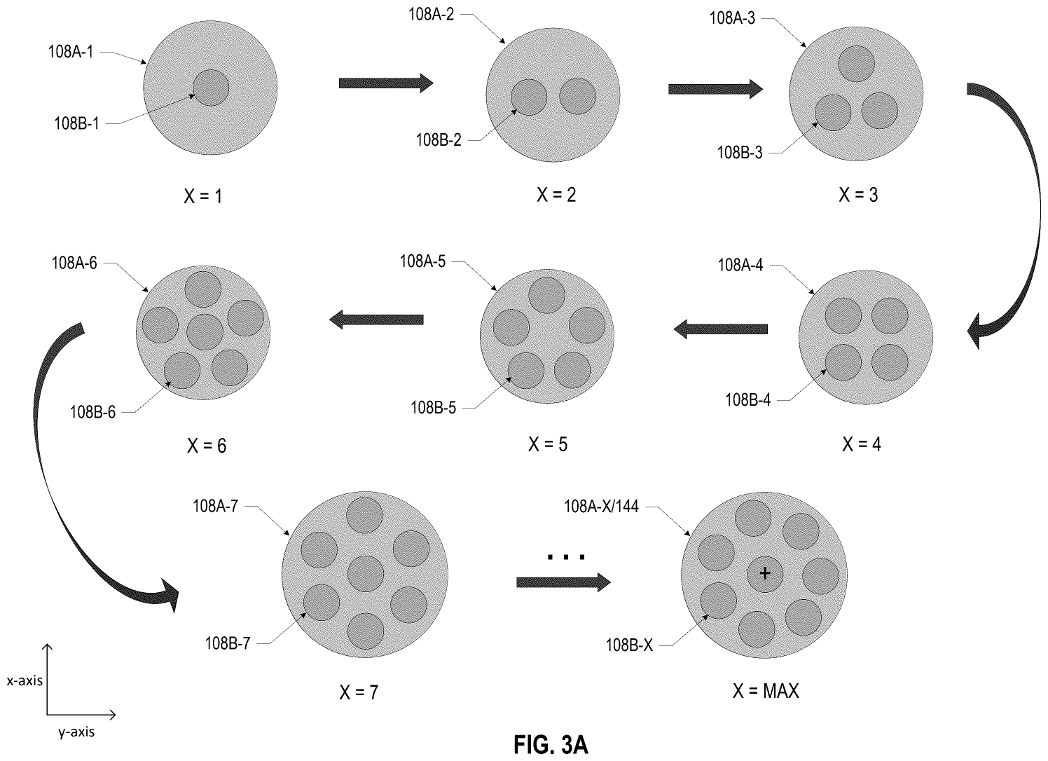

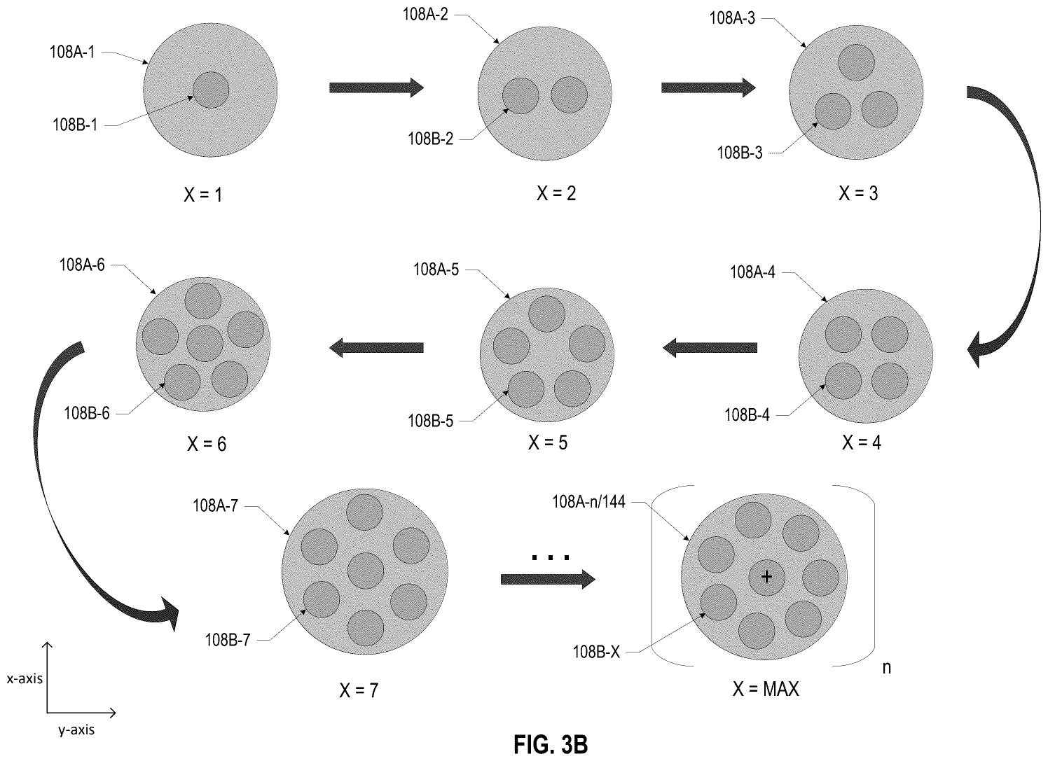

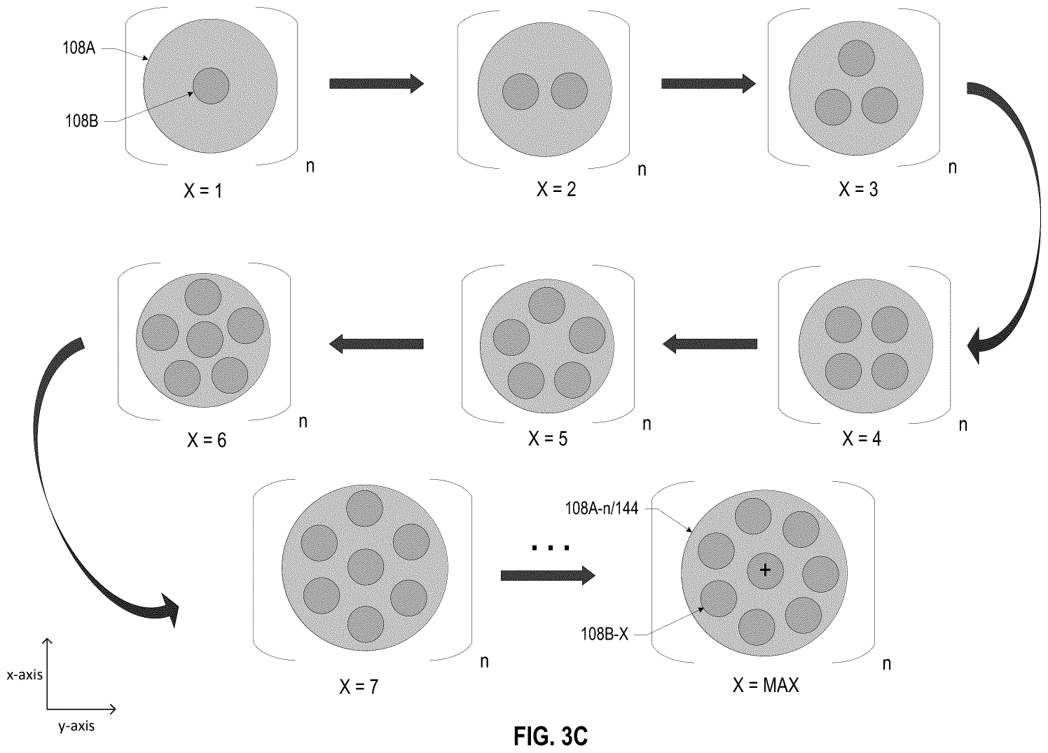

A substrate 107 may include a first surface 170-1 (e.g., a top surface) and an opposing second surface 170-2 (e.g., a bottom surface). A substrate 107 may include N layers of pads 108A, where N is an integer greater than or equal to one; in the accompanying drawings, the pad layers 108A are labeled in ascending order from a top surface (e.g., a first surface 170-1) to a bottom surface (e.g., a second surface 170-2) of the substrate 107 (e.g., layer N, layer N+1, layer N+2, layer N+3, etc.). A substrate 107 may include X vias in via layers 108B between adjacent layers of pads 108A, where X is an integer equal to one or two, and a number of vias coupled to adjacent pad layers increases from the first surface 170-1 towards the second surface 170-2 of the substrate 107 (e.g., X, X+1, X+2, etc.). As shown in FIG. 1A, a substrate 107 may include eight pad layers 108A (e.g., N, N+1, N+2, N+3, N+4, N+5, N+6, and N+7), and seven via layers 108B, where the number of vias increases by one from via layer-to-via layer (e.g., X, X+1, X+2, X+3, X+4, X+5, and X+5). Although FIG. 1A shows a particular number of pad layers 108A, a substrate 107 may include any suitable number of pad layers, for example, between four (4) and thirty-six (36) pad layers. Although FIG. 1A shows a particular number and arrangement of vias in the via layers 108B, a substrate 107 may have any suitable number and arrangement of vias, for example, between four (4) and nineteen (19), as described below in FIGS. 3-5. In some embodiments, the number and arrangement of vias in substrate 107 may have a pyramid shape. In some embodiments, the number and arrangement of vias may have an asymmetrical pyramid shape or an off-center pyramid shape. In particular, the number and arrangement of vias may be determined by a diameter (e.g., xy-dimension) of a BGA pad 144 (e.g., the pad 108A at the second surface 170-2 of the substrate 107 (e.g., as shown in FIG. 1A, the N+7 pad), a diameter of the individual vias 108B, and a required offset or spacing between the vias within a footprint of the BGA pad 144. In some embodiments, a diameter of a via 108B is between 30 microns and 100 microns. In some embodiments, a diameter of a BGA pad 144 may be between 250 microns and 600 microns. In some embodiments, the number and arrangement of vias in a via layer 108B may be determined by a diameter of one or more pads in intervening pad layers 108A (e.g., one or more of layer N+2 through layer N+5). In some embodiments, a number of vias in a via layer 108B may be repeated in a subsequent via layer (e.g., via layers six and seven have X+5 number of vias).

A substrate 107 may include additional conductive pathways 108 arranged through the dielectric material 112 to provide conductive pathways horizontally (e.g., x-direction and y-direction) and vertically (e.g., z-direction) through the substrate 107. In some embodiments, the substrate 107 may include layers of dielectric material 112/conductive material, with lines/traces/pads/contacts (e.g., 108A) of conductive material in one layer electrically coupled to lines/traces/pads/contacts (e.g., 108A) of conductive material in an adjacent layer by vias (e.g., 108B) of the conductive material extending through the dielectric material 112. Conductive elements 108A are generally referred to herein as “pads,” conductive elements 108A also may be referred to herein as “lines,” “traces,” or “contacts.” A substrate 107 including such layers may be formed using any suitable technique, for example, using conventional package substrate manufacturing techniques (e.g., lamination of layers of the dielectric material 112, etc.). In some embodiments, the conductive pathways 108 may be used to route power, ground, and/or signals between a circuit board 102 and one or more top dies 114-1, 114-2. In particular, conductive pathways 108 including alternating pad layers 108A and via layers 108B including an increasing number of vias towards a BGA pad 144 may be used to route signals between a circuit board 102 and one of more top dies 114-1, 114-2 by a high-speed signal path with less reflection at a higher frequency.

In some embodiments, the dielectric material 112 may include an organic dielectric material, such as an organic buildup film, a polyimide, a polyamide, a polyacrylate, an epoxy, a polybenzoxazole, a polyphenyl ether, a polysiloxane, a polynorbornene, or a polyolefin. In some embodiments, the organic dielctric material is photoimageable, such as a photoimageable dielectric (PID), a liquid photoimageable polymer, or a dry film photoimageable polymer. In some embodiments, the dielectric material 112 may include a ceramic, an epoxy film having filler particles therein, glass, an inorganic material, or combinations of organic and inorganic materials, for example. In some embodiments, a material of the conductive pathways 108 may include a metal (e.g., copper).

The substrate 107 may be coupled to a circuit board 102 by interconnects 150. In particular, the top surface of the circuit board 102 may include a conductive contact 146, and a BGA pad 144 on the bottom surface 170-2 of the substrate 107 may be electrically and mechanically coupled to the conductive contact 146 on the top surface of the circuit board 102 by a solder interconnect 150. Interconnects 150 may include any suitable interconnects, including solder balls for a ball grid array arrangement (as shown). In some embodiments, the interconnects 150 may not couple the substrate 107 to a circuit board 102, but may instead couple the substrate 107 to another IC package, an interposer, or any other suitable component. The circuit board 102 may include an insulating material (e.g., a dielectric material formed in multiple layers, as known in the art) and one or more conductive pathways to route power, ground, and signals through the dielectric material (e.g., including conductive traces and/or conductive vias, as shown). The circuit board may be a motherboard, for example. When the circuit board 102 is formed using standard printed circuit board (PCB) processes, the circuit board 102 may include FR-4, and the conductive pathways in the circuit board 102 may be formed by patterned sheets of copper separated by build-up layers of the FR-4. The conductive pathways in the circuit board 102 may be bordered by liner materials, such as adhesion liners and/or barrier liners, as suitable. Any method known in the art for fabrication of the circuit board 102 may be used, and for the sake of brevity, such methods will not be discussed in further detail herein.

In some embodiments, the circuit board 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process. In some embodiments, additional dies and/or additional components may be disposed on the top surface of the die 114-1, 114-2. Additional passive components, such as surface-mount resistors, capacitors, and/or inductors, may be disposed on the top surface or the bottom surface of the circuit board 102.

Microelectronic assembly 100 may further include die 114-1, 114-2. The die 114-1, 114-2 may include a set of conductive contacts 122 on the bottom surface of the die. The die 114-1, 114-2 may be electrically coupled to the pad 108A in the N layer at the first surface 170-1 of the substrate 107 by interconnects 120. The die 114 may include other conductive pathways (e.g., including lines and vias) and/or to other circuitry (not shown) coupled to the respective conductive contacts (e.g., conductive contacts 122, 124) on the surface of the die 114. The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked). In some embodiments, the die 114 may be a memory device or a high frequency serializer and deserializer (SerDes), such as a Peripheral Component Interconnect (PCI) express. In some embodiments, the die 114 may be a processing die, a radio frequency chip, a power converter, a network processor, a workload accelerator, a voltage regulator die, or a security encryptor.

The interconnects (e.g., interconnects 120, 150) disclosed herein may take any suitable form. The interconnects 120 may have a finer pitch than the interconnects 150 in a microelectronic assembly. In some embodiments, the interconnects 150 disclosed herein may have a pitch between 55 microns and 2000 microns, while the interconnects 120 disclosed herein may have a pitch between 25 microns and 250 microns. In some embodiments, a set of interconnects may include solder (e.g., solder bumps or balls that are subject to a thermal reflow to form the interconnects), for example, as shown in FIG. 1A, the interconnects 120 may include solder between a conductive contact 122 on a bottom surface of the die 114-1, 114-2 and a top surface 170-1 of the substrate 107, and the interconnects 150 may include solder between a conductive BGA pad 144 on a bottom surface of the substrate 107 and a conductive contact 146 on a top surface of the circuit board 102.

In some embodiments, interconnects 120 in a microelectronic assembly 100 may be metal-to-metal interconnects (e.g., copper-to-copper interconnects, or plated interconnects). In such embodiments, the interconnect may be bonded together (e.g., under elevated pressure and/or temperature) without the use of intervening solder or an anisotropic conductive material. In some embodiments, interconnects 120 in a microelectronic assembly 100 may be solder interconnects that include a solder with a higher melting point than a solder included in some or all of the interconnects 150. For example, when the interconnects 120 in a microelectronic assembly 100 are formed before the interconnects 150 are formed, solder-based interconnects 120 may use a higher-temperature solder (e.g., with a melting point above 200 degrees Celsius), while the interconnects 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

The microelectronic assembly 100 of FIG. 1A may also include an underfill material 127. In some embodiments, the underfill material 127 may extend between the die 114-1, 114-2 and the top surface 170-1 of the substrate 107 around the associated interconnects 120. In some embodiments, the underfill material 127 (not shown) may extend between the bottom surface 170-2 of the substrate 107 and the top surface of the circuit board 102 around the associated interconnects 150. In some embodiments, a microelectronic assembly 100 may include a solder resist material (not shown) at a top surface 170-1 and/or a bottom surface 170-2 of the substrate 107 to function as a passivation layer. The underfill material 127 may be an insulating material, such as an appropriate epoxy material. In some embodiments, the underfill material 127 may include a capillary underfill, NCF, or molded underfill. In some embodiments, the underfill material 127 may include an epoxy flux that assists with soldering the die 114-1, 114-2 to the substrate 107 when forming the interconnects 120, and then polymerizes and encapsulates the interconnects 120. The underfill material 127 may be selected to have a coefficient of thermal expansion (CTE) that may mitigate or minimize the stress between the substrate 107 and the die 114-1, 114-2 arising from uneven thermal expansion in the microelectronic assembly 100. In some embodiments, the CTE of the underfill material 127 may have a value that is intermediate to the CTE of the substrate 107 (e.g., the CTE of the dielectric material 112 of the substrate 107) and a CTE of the dies 114.

Although FIG. 1A depicts a microelectronic assembly 100 having a substrate with a particular number of dies 114 and conductive pathways 108, this number and arrangement are simply illustrative, and a microelectronic assembly 100 may include any desired number and arrangement of dies 114, including dies embedded within the substrate 107. Although FIG. 1A shows the die 114-1, 114-2 as a single-sided die, the die 114-1, 114-2 may be double-sided dies and may be a single-pitch die or a mixed-pitch die. In this context, a double-sided die refers to a die that has connections on both surfaces. In some embodiments, a double-sided die may include through through-substrate vias (TSVs) to form connections on both surfaces. The active surface of a double-sided die, which is the surface containing one or more active devices and a majority of interconnects, may face either direction depending on the design and electrical requirements.

Many of the elements of the microelectronic assembly 100 of FIG. 1A are included in other ones of the accompanying drawings; the discussion of these elements is not repeated when discussing these drawings, and any of these elements may take any of the forms disclosed herein. Further, a number of elements are illustrated in FIG. 1A as included in the microelectronic assembly 100, but a number of these elements may not be present in a microelectronic assembly 100. For example, in various embodiments, the die 114, the underfill material 127, and the circuit board 102 may not be included. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

FIG. 1B is a schematic cross-sectional view of another example microelectronic assembly according to some embodiments of the present disclosure. The configuration of the embodiment shown in the figure is like that of FIG. 1A, except for differences as described further. The microelectronic assembly 100 may include a substrate 107 having a core 109 with through-core vias 115 with a first portion of the substrate 107-1 below the core 109 (e.g., similar to substrate 107 of FIG. 1A) and a second portion of the substrate 107-2 above the core 109. The second portion of the substrate 107-2 may include a dielectric material 112 with conductive pathways 108. The core 109 may be formed of any suitable material, including glass, a fiber-reinforced epoxy, an organic dielectric material, such as an epoxy, or a phenolic resin or polyimide resin reinforced with glass, aramid, or nylon. The microelectronic assembly 100 of FIG. 1B further illustrates the first portion of the substrate 107-1 having six pad layers 108A (e.g., layer N through layer N+5) and five via layers 108B having a number of vias increasing by one (e.g., X through X+4) from a top surface 170-1 towards a bottom surface 170-2 of the first portion of the substrate 107-1. The through-core vias 115 may be electrically coupled to the pad 108A in the N layer at the top surface 170-1 of the first portion of the substrate 107-1 and to the conductive pathways 108 in the second portion of the substrate 107-2 such that signals may be transmitted between the die 114-1, 114-2 and the circuit board 102.

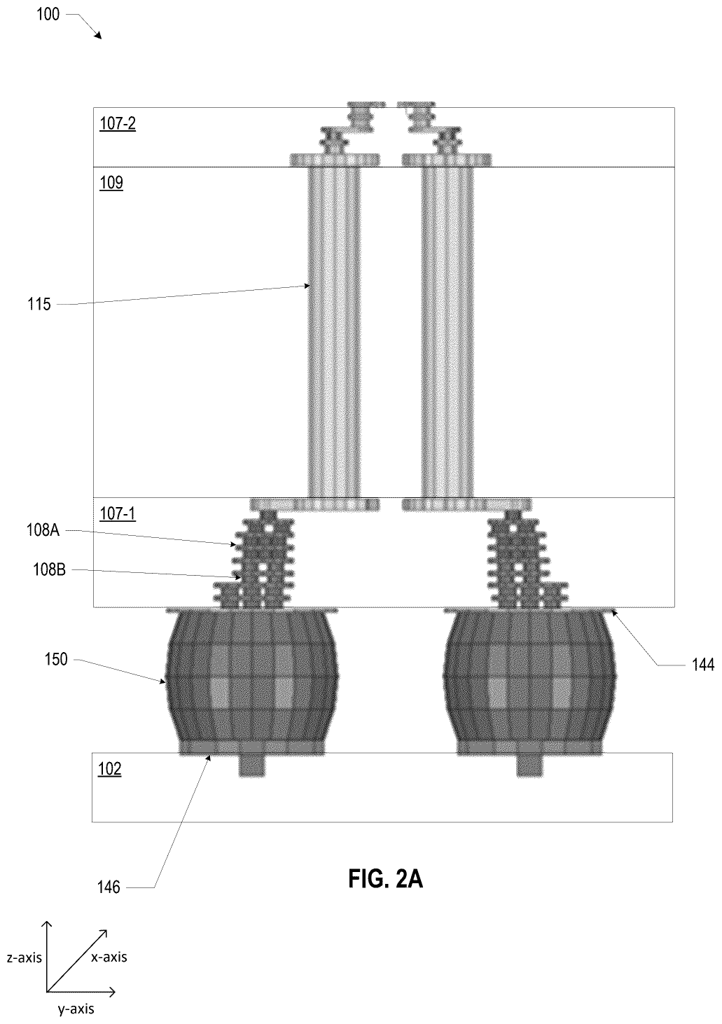

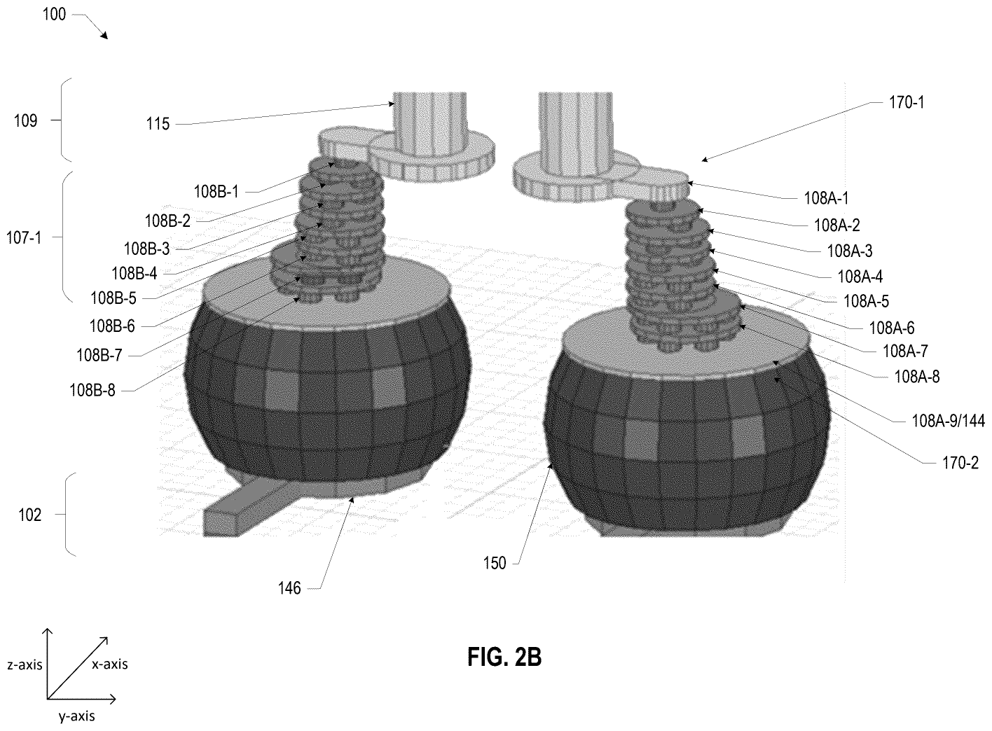

FIG. 2A is a simplified schematic cross-sectional view of another example microelectronic assembly according to some embodiments of the present disclosure. The configuration of the embodiment shown in the figure is like that of FIG. 1B, except for differences as described further. The microelectronic assembly 100 may include a substrate 107 having a core 109 with through-core vias 115 with a first portion of the substrate 107-1 below the core 109 (e.g., similar to substrate 107 of FIG. 1A) and a second portion of the substrate 107-2 above the core 109. The microelectronic assembly 100 of FIG. 2A further illustrates the first portion of the substrate 107-1 having nine pad layers 108A and eight via layers 108B with a number of vias increasing from a top surface 170-1 towards a bottom surface 170-2 of the first portion of the substrate 107-1 (e.g., as shown and described in more detail with reference to FIG. 2B).

FIG. 2B is a magnified, three-dimensional, perspective view of a portion of the microelectronic assembly of FIG. 2A illustrating the conductive pathways 108 of a first portion 107-1 of the substrate 107, the through-core vias 115 of the core 109, and interconnects 150 including solder and pads 144, 146. In particular, FIG. 2B shows nine pad layers 108A-1 through 108A-9 (e.g., beginning with N=1 at the first surface 170-1 of the first portion of the substrate 107-1) and eight via layers 108B-1 through 108B-8. A number of vias (e.g., X, X+1, etc., as shown in FIG. 1) coupled to adjacent pad layers 108A increases towards a BGA pad 144 (e.g., pad layer 108A-9) forming clusters of vias with an off-centered or asymmetrical pyramid shape.

FIG. 3A illustrates bottom views of pad layers and via layers including example numbers and arrangements of vias coupled to the adjacent pad layers that are stacked vertically to form pyramidal shaped via clusters, in accordance with various embodiments. FIG. 3A illustrates a number of vias X increasing by one (e.g., X+1) in each subsequent via layer until a maximum number of vias (e.g., X=MAX) and/or a maximum number of pad layers (e.g., 108A-X) is achieved. As shown in FIG. 3A, a first pad layer 108A-1 may include a first via layer 108B-1 having X number of vias coupled to a bottom surface of the first pad layer 108A-1 (e.g., as shown in FIG. 2B), where X is equal to 1. A second pad layer 108A-2 may include a second via layer 108B-2 having X number of vias coupled to a bottom surface of the second pad layer 108A-2, where X is equal to 2. The first via layer 108B-1 is between the first and second pad layers 108A-1, 108A-2 (e.g., as shown in FIG. 2B). A third pad layer 108A-3 may include a third via layer 108B-3 having X number of vias coupled to a bottom surface of the third pad layer 108A-3, where X is equal to 3. The second via layer 108B-2 is between the second and third pad layers 108A-2, 108A-3 (e.g., as shown in FIG. 2B). A fourth pad layer 108A-4 may include a fourth via layer 108B-4 having X number of vias coupled to a bottom surface of the fourth pad layer 108A-4, where X is equal to 4. The third via layer 108B-3 is between the third and fourth pad layers 108A-3, 108A-4 (e.g., as shown in FIG. 2B). A fifth pad layer 108A-5 may include a fifth via layer 108B-5 having X number of vias coupled to a bottom surface of the fifth pad layer 108A-5, where X is equal to 5. The fourth via layer 108B-4 is between the fourth and fifth pad layers 108A-4, 108A-5 (e.g., as shown in FIG. 2B). A sixth pad layer 108A-6 may include a sixth via layer 108B-6 having X number of vias coupled to a bottom surface of the sixth pad layer 108A-6, where X is equal to 6. The fifth via layer 108B-5 is between the fifth and sixth pad layers 108A-5, 108A-6 (e.g., as shown in FIG. 2B). A seventh pad layer 108A-7 may include a seventh via layer 108B-7 having X number of vias coupled to a bottom surface of the seventh pad layer 108A-7, where X is equal to 7. The sixth via layer 108B-6 is between the sixth and seventh pad layers 108A-6, 108A-7 (e.g., as shown in FIG. 2B). Additional pad layers 108A and via layers 108B may be formed with X number of vias increasing by one for each subsequent via layer 108B until a maximum number of vias (e.g., X=MAX) is achieved and/or a maximum number of pad layers 108A-X is achieved. Pad layer 108A-X may also be referred to as a BGA pad 144. A diameter (e.g., xy-dimension) of a pad in a pad layer 108A may increase as a number of vias X increases. For example, as shown, a diameter of the pad in the seventh pad layer 108A-7 may be greater than a diameter of the pad in the sixth pad layer 108A-6. Although FIG. 3A illustrates pad layers 108A having a pad with a particular size and dimensions (e.g., diameter), a microelectronic assembly may include pad layers 108A having a pad with any suitable size and dimensions. Although FIG. 3A illustrates a first via layer 108B-1 having one via coupled to a bottom surface of the first pad layer 108A-1 (e.g., where X=1), in some embodiments, a first via layer 108B-1 may have two vias coupled to a bottom surface of the first pad layer 108A-1 (e.g., where X=2) and the number of vias increase by one in each subsequent via layer (e.g., X=3 in the second via layer 108B-2, X=4 in the third via layer 108B-3, X=5 in the fourth via layer 108B-4, etc.) until a maximum number of vias (e.g., X=MAX) and/or a maximum number of pad layers (e.g., 108A-X) is achieved.

FIG. 3B illustrates bottom views of pad layers and via layers including example numbers and arrangements of vias coupled to the adjacent pad layers that are stacked vertically to form pyramidal shaped via clusters, in accordance with various embodiments. The configuration of the embodiment shown in the figure is like that of FIG. 3A, except for differences as described further. FIG. 3B illustrates a number of vias X increasing by one in each subsequent via layer until a maximum number of vias (e.g., X=MAX) is achieved and this maximum number of vias (e.g., X=MAX) is repeated (e.g., n) in subsequent via layers until a maximum number of pad layers (e.g., 108A-n) is achieved.

FIG. 3C illustrates bottom views of pad layers and via layers including example numbers and arrangements of vias coupled to the adjacent pad layers that are stacked vertically to form extended, pyramidal shaped via clusters, in accordance with various embodiments. The configuration of the embodiment shown in the figure is like that of FIG. 3A and 3B, except for differences as described further. FIG. 3C illustrates a number of vias X increasing by one in a subsequent via layer, where this number of vias (e.g., X=1, X=2, etc.) may be repeated (e.g., n) in subsequent via layers before the number of vias X increases by one in a subsequent via layer, and this may be continued until a maximum number of vias (e.g., X=MAX) is achieved and/or until a maximum number of pad layers (e.g., 108A-n) is achieved.

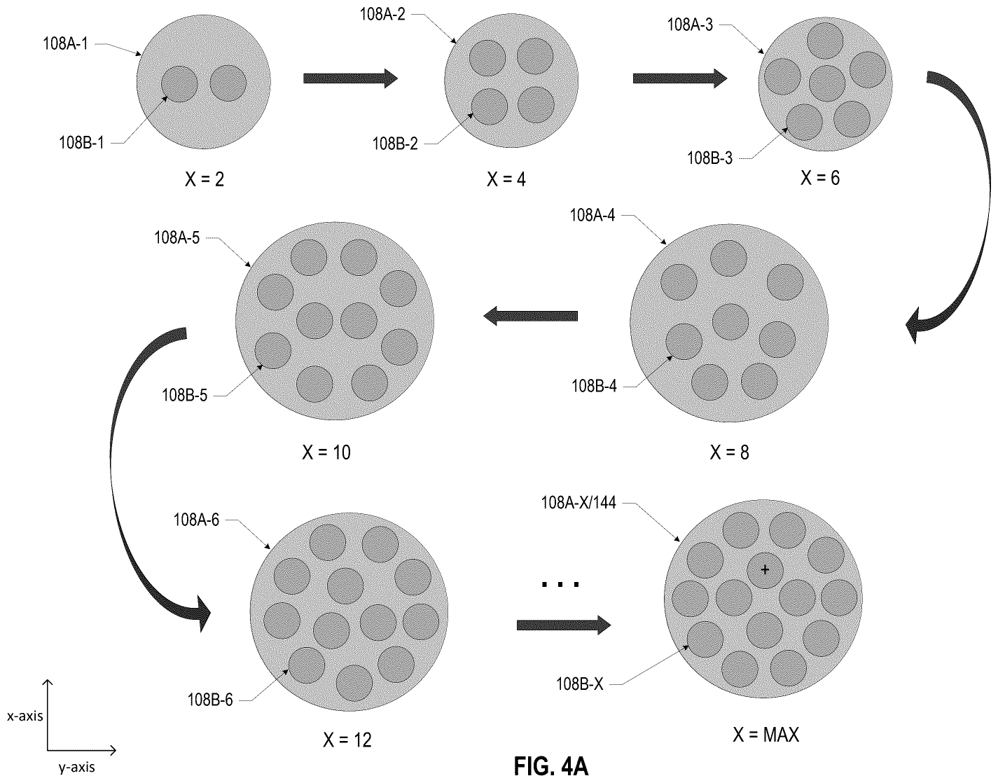

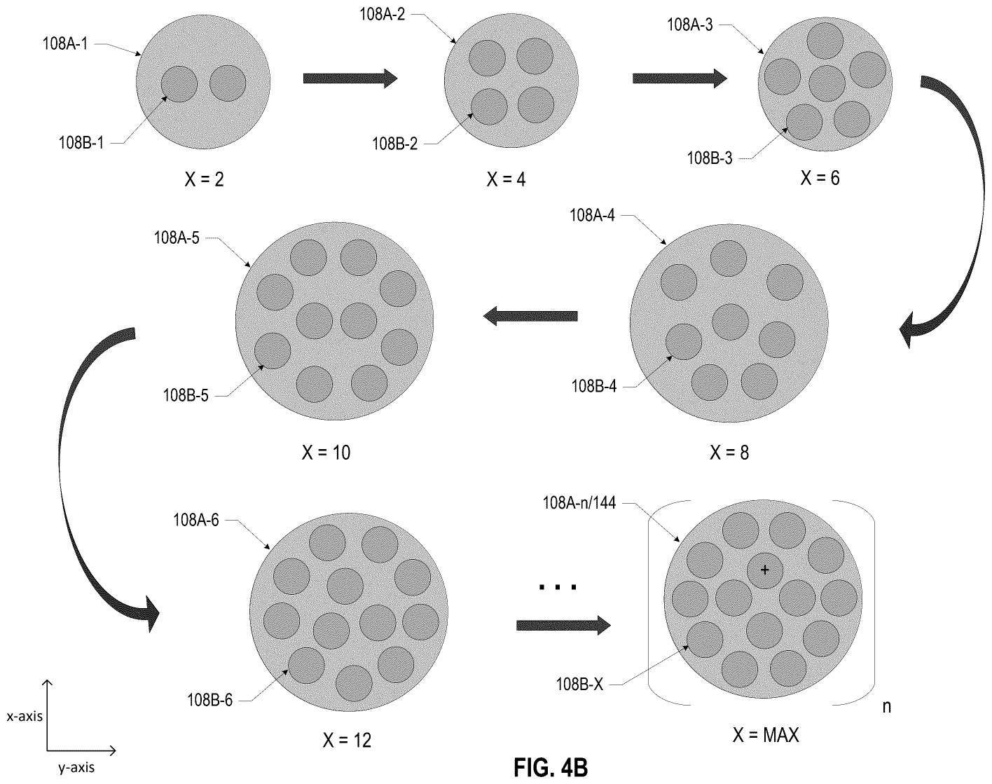

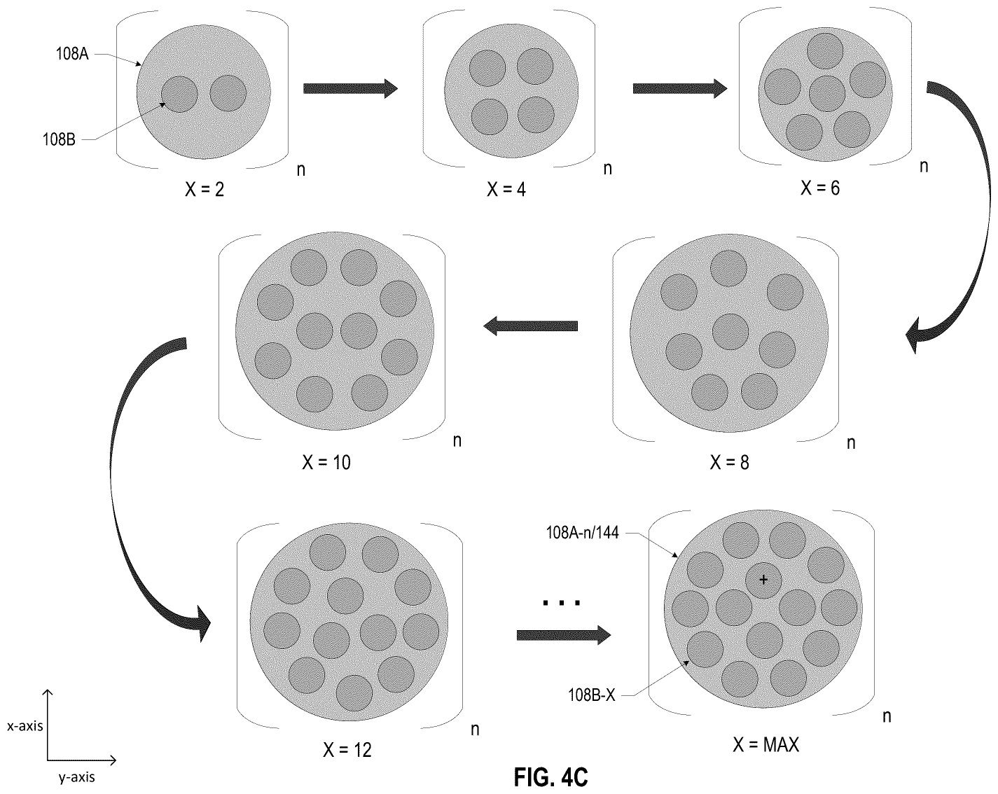

FIG. 4A illustrates bottom views of pad layers and via layers including example numbers and arrangements of vias coupled to the adjacent pad layers that are stacked vertically to form pyramidal shaped via clusters, in accordance with various embodiments. FIG. 4A illustrates a number of vias X increasing by two (e.g., X+2) in each subsequent via layer until a maximum number of vias (e.g., X=MAX) and/or a maximum number of pad layers (e.g., 108A-X) is achieved. As shown in FIG. 4A, a first pad layer 108A-1 may include a first via layer 108B-1 having X number of vias coupled to a bottom surface of the first pad layer 108A-1 (e.g., as shown in FIG. 2B), where X is equal to 2. A second pad layer 108A-2 may include a second via layer 108B-2 having X number of vias coupled to a bottom surface of the second pad layer 108A-2, where X is equal to 4. The first via layer 108B-1 is between the first and second pad layers 108A-1, 108A-2 (e.g., as shown in FIG. 2B). A third pad layer 108A-3 may include a third via layer 108B-3 having X number of vias coupled to a bottom surface of the third pad layer 108A-3, where X is equal to 6. The second via layer 108B-2 is between the second and third pad layers 108A-2, 108A-3 (e.g., as shown in FIG. 2B). A fourth pad layer 108A-4 may include a fourth via layer 108B-4 having X number of vias coupled to a bottom surface of the fourth pad layer 108A-4, where X is equal to 8. The third via layer 108B-3 is between the third and fourth pad layers 108A-3, 108A-4 (e.g., as shown in FIG. 2B). A fifth pad layer 108A-5 may include a fifth via layer 108B-5 having X number of vias coupled to a bottom surface of the fifth pad layer 108A-5, where X is equal to 10. The fourth via layer 108B-4 is between the fourth and fifth pad layers 108A-4, 108A-5 (e.g., as shown in FIG. 2B). A sixth pad layer 108A-6 may include a sixth via layer 108B-6 having X number of vias coupled to a bottom surface of the sixth pad layer 108A-6, where X is equal to 12. The fifth via layer 108B-5 is between the fifth and sixth pad layers 108A-5, 108A-6 (e.g., as shown in FIG. 2B). Additional pad layers 108A and via layers 108B may be formed with X number of vias increasing by two for each subsequent via layer 108B until a maximum number of vias (e.g., X=MAX) is achieved and/or a maximum number of pad layers 108A-X is achieved. Pad layer 108A-X may also be referred to as a BGA pad 144. A diameter (e.g., xy-dimension) of a pad in a pad layer 108A may increase as a number of vias X increases. For example, as shown, a diameter of the pad in the fourth pad layer 108A-4 may be greater than a diameter of the pad in the third pad layer 108A-3. Although FIG. 4A illustrates pad layers 108A having a pad with a particular size and dimensions (e.g., diameter), a microelectronic assembly may include pad layers 108A having a pad with any suitable size and dimensions. Although FIG. 4A illustrates a first via layer 108B-1 having two vias coupled to a bottom surface of the first pad layer 108A-1 (e.g., where X=2), in some embodiments, a first via layer 108B-1 may have one via coupled to a bottom surface of the first pad layer 108A-1 (e.g., where X=1) and the number of vias increase by two in each subsequent via layer (e.g., X=3 in the second via layer 108B-2, X=5 in the third via layer 108B-3, X=7 in the fourth via layer 108B-4, etc.) until a maximum number of vias (e.g., X=MAX) and/or a maximum number of pad layers (e.g., 108A-X) is achieved.

FIG. 4B illustrates bottom views of pad layers and via layers including example numbers and arrangements of vias coupled to the adjacent pad layers that are stacked vertically to form pyramidal shaped via clusters, in accordance with various embodiments. The configuration of the embodiment shown in the figure is like that of FIG. 4A, except for differences as described further. FIG. 4B illustrates a number of vias X increasing by two in each subsequent via layer until a maximum number of vias (e.g., X=MAX) is achieved and this maximum number of vias (e.g., X=MAX) is repeated (e.g., n) in subsequent via layers until a maximum number of pad layers (e.g., 108A-n) is achieved.

FIG. 4C illustrates bottom views of pad layers and via layers including example numbers and arrangements of vias coupled to the adjacent pad layers that are stacked vertically to form extended, pyramidal shaped via clusters, in accordance with various embodiments. The configuration of the embodiment shown in the figure is like that of FIG. 4A and 4B, except for differences as described further. FIG. 4C illustrates a number of vias X increasing by two in a subsequent via layer, where this number of vias (e.g., X=2, X=4, etc.) may be repeated (e.g., n) before the number of vias X increases by two in a subsequent via layer, and this may be continued until a maximum number of vias (e.g., X=MAX) is achieved and/or until a maximum number of pad layers (e.g., 108A-n) is achieved.

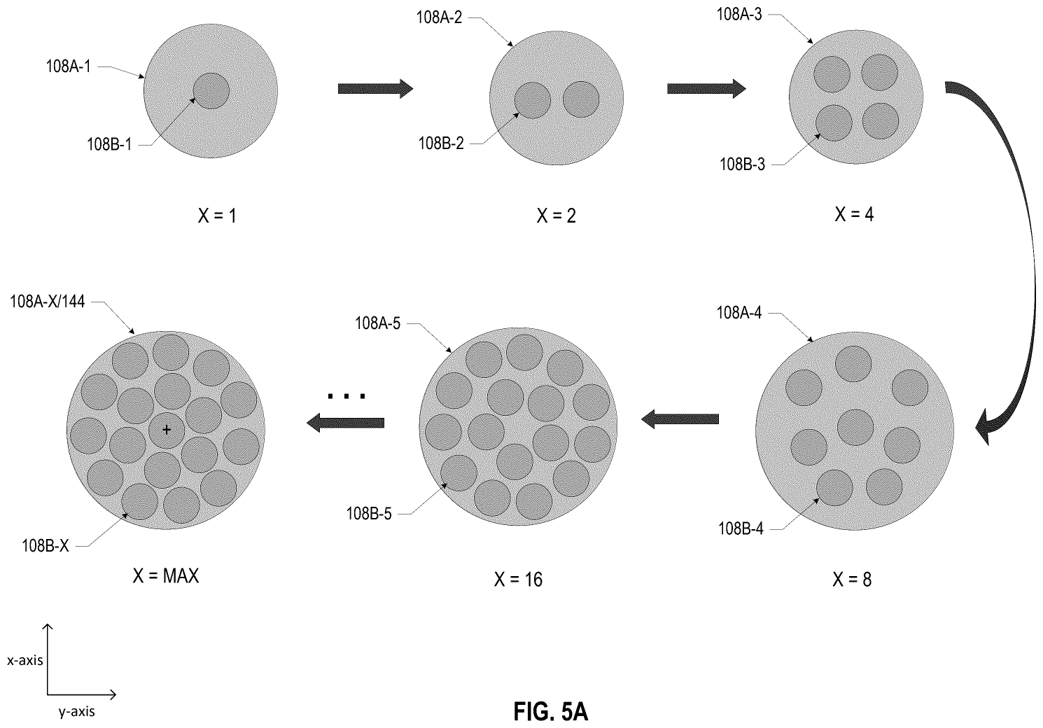

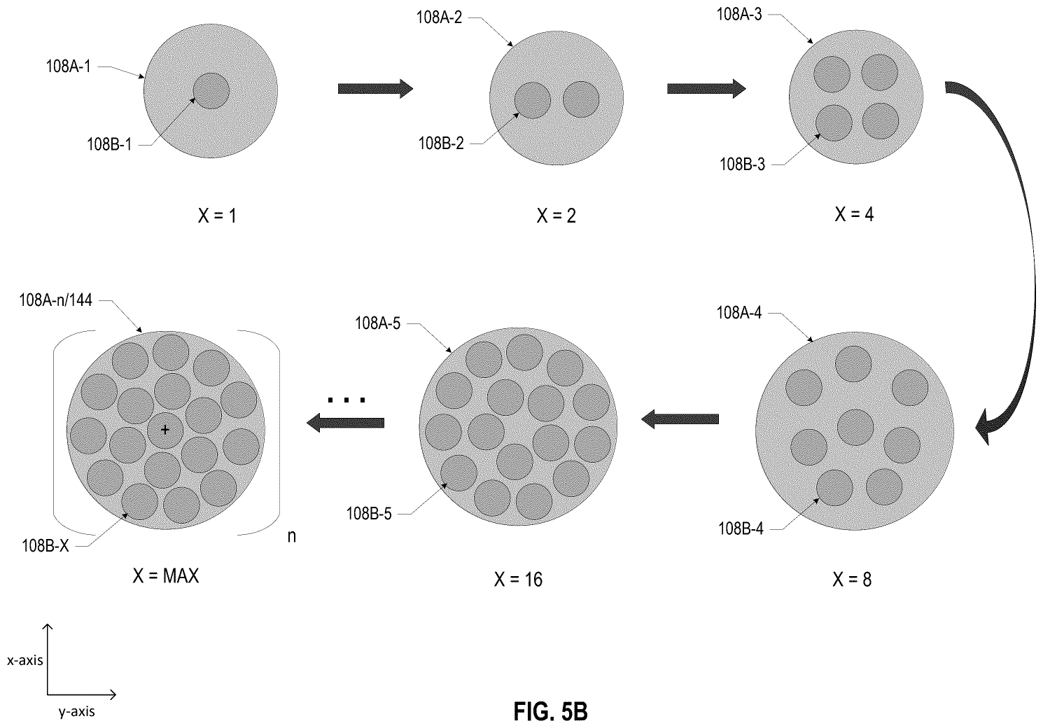

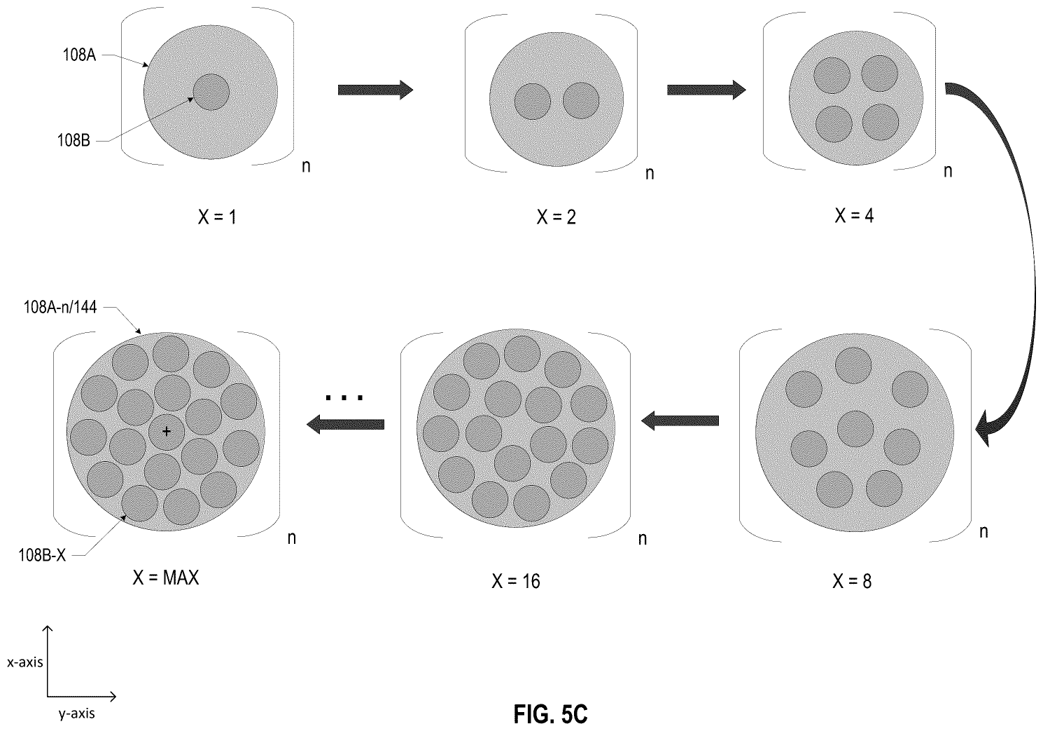

FIG. 5A illustrates bottom views of pad layers and via layers including example numbers and arrangements of vias coupled to the adjacent pad layers that are stacked vertically to form pyramidal shaped via clusters, in accordance with various embodiments. FIG. 5A illustrates a number of vias X increasing by doubling (e.g., 2X) in each subsequent via layer until a maximum number of vias (e.g., X=MAX) and/or a maximum number of pad layers (e.g., 108A-X) is achieved. As shown in FIG. 5A, a first pad layer 108A-1 may include a first via layer 108B-1 having X number of vias coupled to a bottom surface of the first pad layer 108A-1 (e.g., as shown in FIG. 2B), where X is equal to 1. A second pad layer 108A-2 may include a second via layer 108B-2 having X number of vias coupled to a bottom surface of the second pad layer 108A-2, where X is equal to 2. The first via layer 108B-1 is between the first and second pad layers 108A-1, 108A-2 (e.g., as shown in FIG. 2B). A third pad layer 108A-3 may include a third via layer 108B-3 having X number of vias coupled to a bottom surface of the third pad layer 108A-3, where X is equal to 4. The second via layer 108B-2 is between the second and third pad layers 108A-2, 108A-3 (e.g., as shown in FIG. 2B). A fourth pad layer 108A-4 may include a fourth via layer 108B-4 having X number of vias coupled to a bottom surface of the fourth pad layer 108A-4, where X is equal to 8. The third via layer 108B-3 is between the third and fourth pad layers 108A-3, 108A-4 (e.g., as shown in FIG. 2B). A fifth pad layer 108A-5 may include a fifth via layer 108B-5 having X number of vias coupled to a bottom surface of the fifth pad layer 108A-5, where X is equal to 16. The fourth via layer 108B-4 is between the fourth and fifth pad layers 108A-4, 108A-5 (e.g., as shown in FIG. 2B). Additional pad layers 108A and via layers 108B may be formed with X number of vias increasing by doubling for each subsequent via layer 108B until a maximum number of vias (e.g., X=MAX) is achieved and/or a maximum number of pad layers 108A-X is achieved. Pad layer 108A-X may also be referred to as a BGA pad 144. A diameter (e.g., xy-dimension) of a pad in a pad layer 108A may increase as a number of vias X increases. For example, as shown, a diameter of the pad in the fourth pad layer 108A-4 may be greater than a diameter of the pad in the third pad layer 108A-3. Although FIG. 5A illustrates pad layers 108A having a pad with a particular size and dimensions (e.g., diameter), a microelectronic assembly may include pad layers 108A having a pad with any suitable size and dimensions. Although FIG. 5A illustrates a first via layer 108B-1 having one via coupled to a bottom surface of the first pad layer 108A-1 (e.g., where X=1), in some embodiments, a first via layer 108B-1 may have two vias coupled to a bottom surface of the first pad layer 108A-1 (e.g., where X=2) and the number of vias increase by doubling in each subsequent via layer (e.g., X=4 in the second via layer 108B-2, X=8 in the third via layer 108B-3, X=16 in the fourth via layer 108B-4, etc.) until a maximum number of vias (e.g., X=MAX) and/or a maximum number of pad layers (e.g., 108A-X) is achieved.

FIG. 5B illustrates bottom views of pad layers and via layers including example numbers and arrangements of vias coupled to the adjacent pad layers that are stacked vertically to form pyramidal shaped via clusters, in accordance with various embodiments. The configuration of the embodiment shown in the figure is like that of FIG. 5A, except for differences as described further. FIG. 5B illustrates a number of vias X increasing by doubling in each subsequent via layer until a maximum number of vias (e.g., X=MAX) is achieved and this maximum number of vias (e.g., X=MAX) is repeated (e.g., n) in subsequent via layers until a maximum number of pad layers (e.g., 108A-n) is achieved.

FIG. 5C illustrates bottom views of pad layers and via layers including example numbers and arrangements of vias coupled to the adjacent pad layers that are stacked vertically to form extended, pyramidal shaped via clusters, in accordance with various embodiments. The configuration of the embodiment shown in the figure is like that of FIG. 5A and 5B, except for differences as described further. FIG. 5C illustrates a number of vias X increasing by doubling in a subsequent via layer, where this number of vias (e.g., X=1, X=2, X=4, etc.) may be repeated (e.g., n) before the number of vias X increases by doubling in a subsequent via layer, and this may be continued until a maximum number of vias (e.g., X=MAX) is achieved and/or until a maximum number of pad layers (e.g., 108A-n) is achieved.

### Example Devices and Components

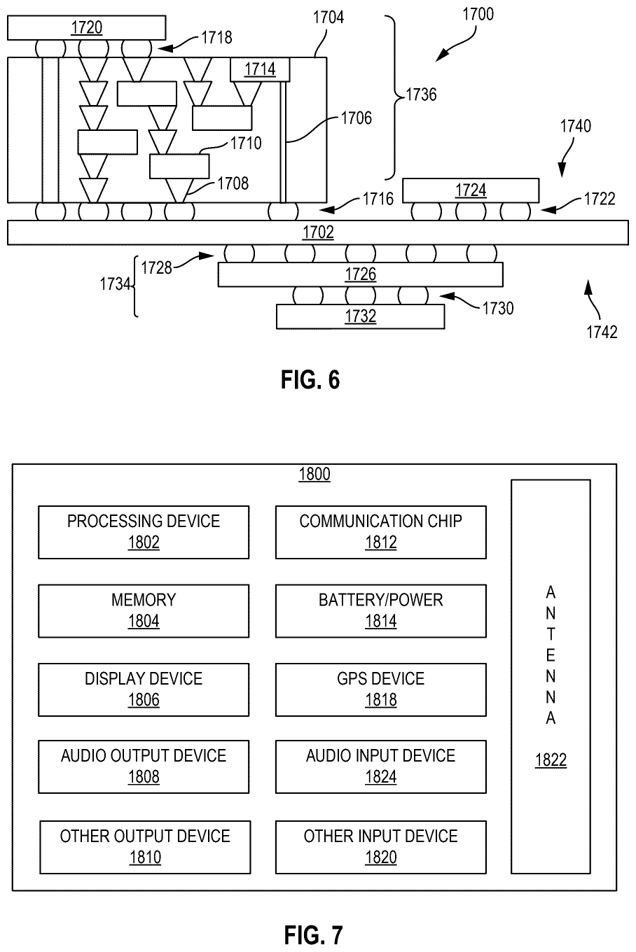

The microelectronic assemblies 100 disclosed herein may be included in any suitable electronic component. FIGS. 6 and 7 illustrate various examples of apparatuses that may include, or be included in, any of the microelectronic assemblies 100 disclosed herein.

FIG. 6 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 6 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 6), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 6, multiple IC packages may be coupled to the interposer 1704; indeed, additional interposers may be coupled to the interposer 1704. The interposer 1704 may provide an intervening substrate used to bridge the circuit board 1702 and the IC package 1720. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 6, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 6 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 7 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 7 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 7, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.
Example 1 is a substrate of a microelectronic assembly, including a first layer including a first conductive pad at a first surface of the substrate; a second layer, adjacent to the first layer, including first conductive vias, wherein one (1) or two (2) first conductive vias are physically coupled to the first conductive pad; a third layer including second conductive vias; and a fourth layer, adjacent to the third layer, including a second conductive pad at a second surface opposite the first surface of the substrate, wherein between four (4) and nineteen (19) second conductive vias are physically coupled to the second conductive pad, and the first conductive pad is electrically coupled to the second conductive pad by at least the first conductive vias and the second conductive vias.
Example 2 may include the subject matter of Example 1, and may further specify that a diameter of the second conductive pad is between 250 microns and 600 microns.
Example 3 may include the subject matter of Example 1 or 2, and may further specify that a diameter of individual second conductive vias is between 30 microns and 100 microns.
Example 4 may include the subject matter of any of Examples 1-3, and may further specify that the third layer includes between eight (8) and nineteen (19) second conductive vias, and the substrate may further include a fifth layer, between the second layer and the third layer, including a third conductive pad; and a sixth layer, adjacent to the fifth layer and between the second layer and the third layer, including between four (4) and eight (8) third conductive vias physically coupled to the third conductive pad, wherein the first conductive pad is electrically coupled to the second conductive pad by at least the first conductive vias, the second conductive vias, and the third conductive vias.
Example 5 may include the subject matter of any of Examples 1-4, and may further specify that a total number of layers including a conductive pad is between four (4) and thirty-six (36) layers.
Example 6 may include the subject matter of any of Examples 1-5, and may further specify that the first conductive vias and the second conductive vias are within a footprint of the second conductive pad.
Example 7 may include the subject matter of any of Examples 1-6, and may further specify that the first conductive vias and the second conductive vias are configured to route signals through the substrate.
Example 8 may include the subject matter of any of Examples 1-7, and may further include a core; and a conductive via, through the core, electrically coupled to the first conductive pad.
Example 9 may include the subject matter of any of Examples 1-8, and may further include solder on the second conductive pad.
Example 10 may include the subject matter of any of Examples 1-9, and may further specify that the substrate includes a dielectric material and the first conductive vias and the second conductive vias extend vertically through the dielectric material.
Example 11 is a microelectronic assembly, including a substrate including alternating layers of pads and vias, the substrate including a first pad layer, at a first surface of the substrate, including a first conductive pad; a first via layer, adjacent to the first pad layer, including between one (1) or two (2) first conductive vias; a second pad layer, adjacent to the first via layer, including a second conductive pad, wherein the first conductive vias are physically coupled to the first conductive pad and the second conductive pad; a second via layer, adjacent to the second pad layer, including between two (2) and four (4) second conductive vias; a third pad layer, adjacent to the second via layer, including a third conductive pad, wherein the second conductive vias are physically coupled to the second conductive pad and the third conductive pad; a third via layer, adjacent to the third pad layer, including between four (4) and nineteen (19) third conductive vias; a fourth pad layer, adjacent to the third via layer and at a second surface of the substrate opposite the first surface of the substrate, including a fourth conductive pad, wherein the third conductive vias are physically coupled to the third conductive pad and the fourth conductive pad; and a die electrically coupled to the first conductive pad of the substrate by an interconnect.
Example 12 may include the subject matter of Example 11, and may further specify that a diameter of the fourth conductive pad is between 250 microns and 600 microns.
Example 13 may include the subject matter of Example 11 or 12, and may further specify that a diameter of individual first conductive vias is between 30 microns and 100 microns.
Example 14 may include the subject matter of any of Examples 11-13, and may further specify that a diameter of individual second conductive vias is between 30 microns and 100 microns.
Example 15 may include the subject matter of any of Examples 11-14, and may further specify that the third via layer includes between eight (8) and nineteen (19) second conductive vias, and the substrate may further include a fifth pad layer, between the second via layer and the third pad layer, including a fifth conductive pad; and a fourth via layer, adjacent to the fifth pad layer and between the second via layer and the third pad layer, including between four (4) and eight (8) fourth conductive vias physically coupled to the fifth conductive pad and the third conductive pad, wherein the first conductive pad is electrically coupled to the fourth conductive pad by at least the first conductive vias, the second conductive vias, the third conductive vias, and the fourth conductive vias.
Example 16 may include the subject matter of any of Examples 11-15, and may further specify that a total number of pad layers is between four (4) and thirty-six (36) layers.
Example 17 may include the subject matter of any of Examples 11-16, and may further specify that the first conductive vias, the second conductive vias, and the third conductive vias are within a footprint of the fourth conductive pad.
Example 18 may include the subject matter of any of Examples 11-17, and may further specify that the first conductive vias, the second conductive vias, and the third conductive vias are configured to route signals through the substrate.
Example 19 may include the subject matter of any of Examples 11-18, and may further specify that the substrate is a first portion of the substrate, and the microelectronic assembly may further include a core at the first surface of the first portion of the substrate; a conductive via, through the core, electrically coupled to the first conductive pad; and a second portion of the substrate on the core at a surface opposite the first portion of the substrate.
Example 20 may include the subject matter of any of Examples 11-19, and may further specify that the interconnect is a first interconnect, and the microelectronic assembly may further include a circuit board electrically coupled to the fourth conductive pad of the substrate by a second interconnect including solder.
Example 21 is a microelectronic assembly, including a substrate having a first conductive pad at a first surface, a second conductive pad at a second surface opposite the first surface, and a plurality of layers between the first surface and the second surfaces, the substrate including a first layer of the plurality of layers including X conductive vias electrically coupled to the first conductive pad, wherein X equals 1 or 2; a second layer of the plurality of layers including a third conductive pad; a third layer of the plurality of layers including Y conductive vias electrically coupled to the third conductive pad, wherein Y is greater than X; a fourth layer of the plurality of layers including Z conductive vias electrically coupled to the second conductive pad at the second surface, wherein Z is greater than or equal to Y; and the first conductive pad is electrically coupled to the second conductive pad by at least the X, Y, and Z conductive vias; and a solder material on the second conductive pad.
Example 22 may include the subject matter of Example 21, and may further specify that Y=X+1.
Example 23 may include the subject matter of Example 21, and may further specify that Y=X+2.
Example 24 may include the subject matter of Example 21, and may further specify that Y=2X.
Example 25 may include the subject matter of any of Examples 21-24, and may further specify that a diameter of the second conductive pad is between 250 microns and 600 microns.
Example 26 may include the subject matter of any of Examples 21-25, and may further specify that a diameter of individual X conductive vias is between 30 microns and 100 microns.
Example 27 may include the subject matter of any of Examples 21-26, and may further specify that a diameter of individual Y conductive vias is between 30 microns and 100 microns.
Example 28 may include the subject matter of any of Examples 21-27, and may further specify that a diameter of individual Z conductive vias is between 30 microns and 100 microns.
Example 29 may include the subject matter of any of Examples 21-28, and may further specify that the X, Y, and Z conductive vias are within a footprint of the second conductive pad.
Example 30 may include the subject matter of any of Examples 21-29, and may further specify that the X, Y, and Z conductive vias are configured to route signals through the substrate.
Example 31 may include the subject matter of any of Examples 21-30, and may further include a circuit board electrically coupled to the second conductive pad of the substrate by an interconnect including the solder material.

1. A substrate of a microelectronic assembly, comprising:
a first layer including a first conductive pad at a first surface of the substrate;
a second layer, adjacent to the first layer, including first conductive vias, wherein one (1) or two (2) first conductive vias are physically coupled to the first conductive pad;
a third layer including second conductive vias; and
a fourth layer, adjacent to the third layer, including a second conductive pad at a second surface opposite the first surface of the substrate, wherein between four (4) and nineteen (19) second conductive vias are physically coupled to the second conductive pad, and the first conductive pad is electrically coupled to the second conductive pad by at least the first conductive vias and the second conductive vias.

2. The substrate of claim 1, wherein a diameter of the second conductive pad is between 250 microns and 600 microns.

3. The substrate of claim 1, wherein a diameter of individual second conductive vias is between 30 microns and 100 microns.

4. The substrate of claim 1, wherein the third layer includes between eight (8) and nineteen (19) second conductive vias, and the substrate further comprising:
a fifth layer, between the second layer and the third layer, including a third conductive pad; and
a sixth layer, adjacent to the fifth layer and between the second layer and the third layer, including between four (4) and eight (8) third conductive vias physically coupled to the third conductive pad, wherein the first conductive pad is electrically coupled to the second conductive pad by at least the first conductive vias, the second conductive vias, and the third conductive vias.

5. The substrate of claim 1, wherein a total number of layers including a conductive pad is between four (4) and thirty-six (36) layers.

6. The substrate of claim 1, wherein the first conductive vias and the second conductive vias are within a footprint of the second conductive pad.

7. The substrate of claim 1, wherein the first conductive vias and the second conductive vias are configured to route signals through the substrate.

8. The substrate of claim 1, further comprising:
solder on the second conductive pad.

9. A microelectronic assembly, comprising:
a substrate including alternating layers of pads and vias, the substrate comprising:
a first pad layer, at a first surface of the substrate, including a first conductive pad;
a first via layer, adjacent to the first pad layer, including between one (1) or two (2) first conductive vias;
a second pad layer, adjacent to the first via layer, including a second conductive pad, wherein the first conductive vias are physically coupled to the first conductive pad and the second conductive pad;
a second via layer, adjacent to the second pad layer, including between two (2) and four (4) second conductive vias;
a third pad layer, adjacent to the second via layer, including a third conductive pad, wherein the second conductive vias are physically coupled to the second conductive pad and the third conductive pad;
a third via layer, adjacent to the third pad layer, including between four (4) and nineteen (19) third conductive vias;
a fourth pad layer, adjacent to the third via layer and at a second surface of the substrate opposite the first surface of the substrate, including a fourth conductive pad, wherein the third conductive vias are physically coupled to the third conductive pad and the fourth conductive pad; and
a die electrically coupled to the first conductive pad of the substrate by an interconnect.

10. The microelectronic assembly of claim 9, wherein a diameter of the fourth conductive pad is between 250 microns and 600 microns.

11. The microelectronic assembly of claim 9, wherein a diameter of individual second conductive vias is between 30 microns and 100 microns.

12. The microelectronic assembly of claim 9 wherein the third via layer includes between eight (8) and nineteen (19) second conductive vias, and the substrate further comprising:
a fifth pad layer, between the second via layer and the third pad layer, including a fifth conductive pad; and
a fourth via layer, adjacent to the fifth pad layer and between the second via layer and the third pad layer, including between four (4) and eight (8) fourth conductive vias physically coupled to the fifth conductive pad and the third conductive pad, wherein the first conductive pad is electrically coupled to the fourth conductive pad by at least the first conductive vias, the second conductive vias, the third conductive vias, and the fourth conductive vias.

13. The microelectronic assembly of claim 9, wherein a total number of pad layers is between four (4) and thirty-six (36) layers.

14. The microelectronic assembly of claim 9, wherein the first conductive vias, the second conductive vias, and the third conductive vias are within a footprint of the fourth conductive pad.

15. The microelectronic assembly of claim 9, wherein the substrate is a first portion of the substrate, and the microelectronic assembly further comprising:
a core at the first surface of the first portion of the substrate;
a conductive via, through the core, electrically coupled to the first conductive pad; and
a second portion of the substrate on the core at a surface opposite the first portion of the substrate.

16. A microelectronic assembly, comprising:
a substrate having a first conductive pad at a first surface, a second conductive pad at a second surface opposite the first surface, and a plurality of layers between the first surface and the second surfaces, the substrate including:
a first layer of the plurality of layers including X conductive vias electrically coupled to the first conductive pad, wherein X equals 1 or 2;
a second layer of the plurality of layers including a third conductive pad;
a third layer of the plurality of layers including Y conductive vias electrically coupled to the third conductive pad, wherein Y is greater than X;
a fourth layer of the plurality of layers including Z conductive vias electrically coupled to the second conductive pad at the second surface, wherein Z is greater than or equal to Y; and the first conductive pad is electrically coupled to the second conductive pad by at least the X, Y, and Z conductive vias; and
a solder material on the second conductive pad.

17. The microelectronic assembly of claim 16, wherein Y=X+1.

18. The microelectronic assembly of claim 16, wherein Y=X+2.

19. The microelectronic assembly of claim 16, wherein Y=2X.

20. The microelectronic assembly of claim 16, further comprising:
a circuit board electrically coupled to the second conductive pad of the substrate by an interconnect including the solder material.
